(19) United States
(12) Patent Application Publication
(10) Pub. No.: US 2024/0215320 A1
(43) Pub. Date: Jun. 27, 2024

(54) LIGHT EMITTING DISPLAY DEVICE

(71) Applicant: LG Display Co., Ltd., Seoul (KR)

(72) Inventor: Mi Kyung PARK, Paju-si (KR)

(21) Appl. No.: 18/356,017

(22) Filed: Jul. 20, 2023

(30) Foreign Application Priority Data
Dec. 21, 2022 (KR) 10-2022-0180752

(51) Int. Cl. H10K 59/122; H10K 59/12

(52) U.S. Cl. CPC H10K 59/122; H10K 59/1201; H10K 59/131

(57) ABSTRACT

Disclosed is a light emitting display device including a substrate having an active area, a plurality of anodes spaced apart from each other in the active area, a bank configured to expose an emissive portion of each of the plurality of anodes, the bank being provided between emissive portions of the plurality of anodes, and a light emitting unit and a cathode sequentially provided on the plurality of anodes and the bank, wherein at least a part of the bank includes a first trench structure asymmetric at both sides thereof.

### CROSS-REFERENCE TO RELATED APPLICATION(S)

This application claims the benefit of Korean Patent Application No. 10-2022-0180752, filed on Dec. 21, 2022, which is hereby incorporated by reference as if fully set forth herein.

### BACKGROUND

### Technical Field

The present disclosure relates to a light emitting display device, and more particularly to a light emitting display device capable of preventing light leakage at the edge of an active area.

### Description of the Related Art

An image display device capable of displaying various kinds of information on a screen is core technology of the information and communication age, and various display devices having excellent performance, including slimness, light weight, and low power consumption, have been continuously developed.

A known light emitting display device includes a light emitting element, which is a self-emissive element. As a result, a separate light source used in a non-emissive element is not necessary, and therefore light weight and slimness of the light emitting display device are possible.

The light emitting element includes a light emitting unit between an anode and a cathode, and an electric field is applied between the anode and the cathode to emit light.

Here, the light emitting unit may have a plurality of layers, including a common layer and an emissive layer, and may include a layer that exhibits high charge mobility, such as a charge generation layer.

Meanwhile, in the light emitting display device, the light emitting element is provided for each subpixel. In the light emitting display device, at least one of layers constituting the light emitting element may be continuous over all of the subpixels in a planar shape.

### BRIEF SUMMARY

Accordingly, the present disclosure is directed to a light emitting display device that substantially obviates one or more problems due to limitations and disadvantages of the related art.

In a light emitting display device, the inventors have realized that leakage current may flow between adjacent subpixels through common layers connected to each other in a planar shape. In the present disclosure a trench that lengthens a path of current that flows to sides between adjacent subpixels may be provided at a bank in order to prevent leakage current between the adjacent subpixels. It is an object of the present disclosure to provide a light emitting display device configured to have a structure in which, in a bank including a trench, the bank is asymmetrically formed such that a common layer is uniformly deposited at the side and the bottom corner of the trench located at the edge of an active area and a method of manufacturing the same.

Additional advantages, objects, and features of the present disclosure will be set forth in part in the description which follows and in part will become apparent to those having ordinary skill in the art upon examination of the following or may be learned from practice of the present disclosure. The objectives and other advantages of the present disclosure may be realized and attained by the structure particularly pointed out in the written description and claims hereof as well as the appended drawings.

To achieve these objects and other advantages and in accordance with the purpose of the present disclosure, as embodied and broadly described herein, a light emitting display device according to the present disclosure is configured to have a structure in which a bank provided at the edge of an active area of a substrate in at least one direction is formed such that heights and taper angles of both sides of the bank are different from each other based on a trench, whereby a material for deposition is uniformly deposited over the entirety of the substrate.

A light emitting display device according to an embodiment of the present disclosure includes a substrate having an active area, a plurality of anodes spaced apart from each other in the active area, a bank configured to expose an emissive portion of each of the plurality of anodes, the bank being provided between emissive portions of the plurality of anodes, and a light emitting unit and a cathode sequentially provided on the plurality of anodes and the bank, wherein at least a part of the bank includes a first trench structure asymmetric at both sides thereof.

In one embodiment, the disclosure provides a light emitting display device comprising a substrate having an active area. A plurality of subpixels positioned in the active area, each subpixel having an anode on the substrate, a light emitting stack on the anode and a cathode on the light emitting stack. A bank is positioned between first sub-pixel and a second subpixel of the plurality of subpixels. A trench is in the bank, the trench being located between the first and second subpixels and the bank has a first wall of a first height adjacent to a first side of the trench and a second wall of second, different height adjacent to second wall of the trench, the first and second walls being positioned between the first and second subpixels.

In one embodiment, the trench has a first sidewall adjacent to the first wall and a second sidewall adjacent to the second wall. The angle of the first sidewall relative to the first substrate is greater than the angle of the second sidewall to the relative to the substrate.

It is to be understood that both the foregoing general description and the following detailed description of the present disclosure are exemplary and explanatory and are intended to provide further explanation of the present disclosure as claimed.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a plan view of a master substrate used to manufacture a plurality of light emitting display devices according to the present disclosure;

FIG. 2 is an enlarged view of area P of FIG. 1;

FIG. 3 is a sectional view taken along line I-I′ of FIG. 2 showing an embodiment of the disclosure;

FIG. 4 is an isometric view showing some of the steps in the process of the master substrate of FIG. 1 during manufacturing of the plurality of light emitting display devices according to the present disclosure with the substrate inverted from the position shown in FIG. 3;

FIG. 5 is a partial sectional view of column A and column D when a comparative process is being carried out with the structure as shown in FIG. 4;

FIG. 6 is a partial sectional view of a general light emitting display device in which short circuit may occur when carrying out the comparative process in a manner shown in FIG. 4;

FIG. 7 is a partial sectional view of the manufacture of a light emitting display device according to a first embodiment of the present disclosure;

FIG. 8 is an enlarged sectional view of area S of FIG. 7;

FIG. 9 is a sectional view of a light emitting display device according to a second embodiment of the present disclosure that is an improvement over the comparative process;

FIG. 10 is a sectional view of FIG. 4 that shows a substrate in position to be manufactured for use in the light emitting display device according to the present disclosure; and

FIGS. 11A to 11D are sectional views showing the structure of FIG. 2 in various stages of the manufacturing process according to the present disclosure.

### DETAILED DESCRIPTION

Advantages and features of the present disclosure and methods of achieving the same will be more clearly understood from embodiments described below with reference to the accompanying drawings. However, the present disclosure is not limited to the following embodiments and may be implemented in various different forms. The embodiments are provided merely to complete the present disclosure and to fully inform a person having ordinary skill in the art to which the present disclosure pertains of the category of the present disclosure.

In the drawings for explaining the exemplary embodiments of the present disclosure, for example, the illustrated shape, size, dimensions (e.g., length, width, height, thickness, radius, diameter, area, etc.), ratio, angle, and number are given by way of example, and thus, are not limitative of the present disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear. A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terms “comprises,” “includes,” and “has,” used in this specification, do not preclude the presence or addition of other elements unless used along with the term “only.” The singular forms are intended to include the plural forms as well, unless the context clearly indicates otherwise.

In the interpretation of constituent elements, the constituent elements are interpreted as including an error range even if there is no explicit description thereof.

When describing positional relationships, for example, when the positional relationship between two parts is described using “on,” “above,” “below,” “beside,” or the like, one or more other parts may be located between the two parts unless the term “directly” or “closely” is used therewith.

When the temporal relationship between two actions is described using “after,” “subsequently,” “next,” “before,” or the like, the actions may not occur in succession unless the term “immediately” or “directly” is used therewith.

Although the terms “first,” “second,” etc., may be used to describe various elements, the elements are not limited by the terms. These terms are merely used to distinguish an element from another element. Therefore, a “first element” described hereinafter may be a “second element” within the technical idea of the present disclosure.

The expressions “first horizontal axis direction,” “second horizontal axis direction,” and “vertical axis direction” must not be interpreted based only on the geometrical relationship therebetween, e.g., the relationship in which the directions are perpendicular to each other, and may mean as having wider directivities within a range within which the construction of the present disclosure is functionally operated.

The expression “at least one” must be interpreted as including all possible combinations selectable from one or more relative items. For example, the expression “at least one of a first item, a second item, and a third item” may mean not only any one of the first item, the second item, and the third item but also all possible combinations of two or more selectable from the first item, the second item, and the third item.

Features of various examples of the present disclosure may be partially or entirely coupled to or combined with each other, various kinds of linkage and driving are technically possible, and the examples may be independently implemented or may be implemented in the state in which the examples are linked with each other.

Hereinafter, preferred embodiments of a light emitting display device according to the present disclosure will be described in detail with reference to the accompanying drawings.

When elements of the drawings are denoted by reference symbols, the same elements may be denoted by the same reference symbols even when they are depicted in different drawings. In addition, the scale of elements shown in the accompanying drawings is different from the actual scale thereof for convenience of description, and therefore the scale of elements is not limited to the scale shown in the drawings.

FIG. 1 is a plan view of a master substrate 10 used to manufacture a plurality of light emitting display devices according to the present disclosure. The master substrate 10 of FIG. is the substrate used during the manufacturing process to conveniently form a plurality of unit cells 11 at the same time in the same process steps. The master substrate 10 can be diced or cut into individual unit cells 11 that are on a final substrate after they are formed on the master substrate.

Referring to FIG. 1, a plurality of unit cells 11, each of which includes an active area 13, may be provided on the master substrate 10 so as to be spaced apart from each other. The active area 13 of each of the plurality of unit cells 11 may include a plurality of emissive portions, and a non-emissive portion may be provided between the plurality of emissive portions. The unit cells 11 may each be subpixels. Thus, each subpixel may be considered a unit cell. That is, the light emitting display device according to the present disclosure may include an active area 13, in which an image is displayed, and an outer area 15 around the active area 13, in which no image is displayed. The master substrate 10 may be a glass substrate or a flexible plastic substrate. As an example, the plastic substrate may include polyimide or polyamide.

In the outer area 15, a common voltage line 17 configured to apply common voltage to the emissive portions of the active area 13 may be provided along the outer area 15. Both ends of the common voltage line 17 may extend to the outside of the unit cell 11 so as to be connected to a printed circuit board configured to generate an electrical signal and to supply power source voltage at the outside thereof. In addition, a plurality of pads configured to provide a signal to the active area 13 may be formed in the outer area 15, and the plurality of pads may include a plurality of gate pads connected to gate lines and a plurality of data pads connected to data lines.

The plurality of unit cells 11 may be arranged in a first direction, and the plurality of unit cells arranged in the first direction may be disposed in a second direction perpendicular to the first direction so as to be included in columns A, B, C, and D. However, the present disclosure is not limited thereto, and the plurality of unit cells 11 may have different sizes and may be disposed in various forms. In one embodiment, each subpixel is a unit cell. In other embodiments, a unit cell might be a group of subpixels, with each unit cell being comprised of one complete pixel. The unit cells might include other circuit structures besides a pixel in one embodiment and it might also be viewed a group of a selected number of pixels. Alternatively, there could be only one unit cell in the light emitting display device.

In the present disclosure, the master substrate 10, on which the plurality of unit cells 11 is provided, may include a first outer line area OLA and a second outer line area OLB of columns A and D opposite each other in the first direction and a central area CA between the first and second outer line areas OLA and OLB. The central area CA may include columns B and C, and may further include areas of columns A and D excluding the first and second outer line areas OLA and OLB.

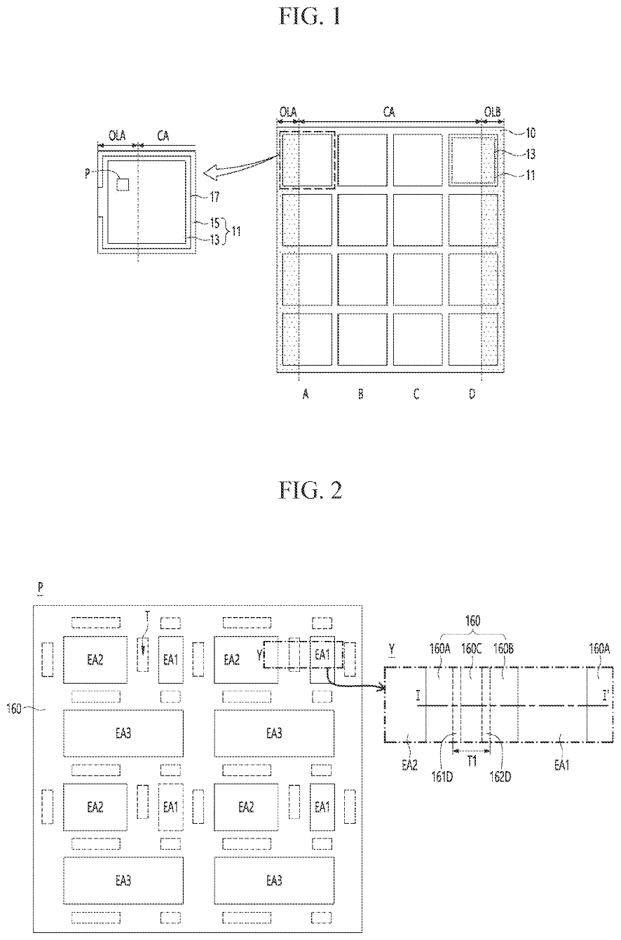

Referring to FIG. 2, which is an enlarged view of area P of FIG. 1, the plurality of emissive portions may include a first emissive portion EA1, a second emissive portion EA2 having a wider area than the first emissive portion EA1, the second emissive portion EA2 being disposed adjacent to the first emissive portion EA1 in a first direction, and a third emissive portion EA3 having a wider area than each of the first emissive portion EA1 and the second emissive portion EA2, the third emissive portion EA3 being disposed adjacent to the first emissive portion EA1 and the second emissive portion EA2, wherein the first to third emissive portions EA1, EA2, and EA3 may be regularly arranged. Here, the first, second, and third emissive portions EA1, EA2, and EA3 may emit red light, green light, and blue light, respectively. However, the disposition of the emissive portions of the present disclosure is not limited thereto. Blue emissive portions and first green emissive portions may be alternately arranged in a diagonal direction, and second green emissive portions and red emissive portions may be alternately arranged in a diagonal direction parallel to the blue emissive portions and the first green emissive portions.

A bank 160 exposes the plurality of emissive portions, and may include trenches T between the plurality of emissive portions. The trenches T may be disposed between the first emissive portion EA1 and the second emissive portion EA2 while some of the trenches T are closer to the third emissive portion EA3. In addition, the trenches T may be provided between the third emissive portion EA3 and each of the first emissive portion EA1 and the second emissive portion EA2. The trenches T may be parallel to the common voltage line provided at the outer area 15 of the unit cell 11.

In area Y of FIG. 2, the trench T between the second emissive portion EA2 and the first emissive portion EA1 is shown in an enlarged state. Referring to area Y of FIG. 2, the bank 160 may include a first area 160A, a second area 160B, and a third area 160C between the first and second areas 160A and 160B, wherein a first side surface 161D may be provided between the first and third areas 160A and 160C, and a second side surface 162D may be provided between the second and third areas 160B and 160C. The trench T of the bank 160 may include a first side surface 161D, a third area 160C, and a second side surface 162D.

The bank 160 of the light emitting display device according to the present disclosure may be disposed asymmetric with respect to the third area 160C in directions toward the first emissive portion EA1 and the second emissive portion EA2. That is, the bank 160 of the light emitting display device according to the present disclosure may have an asymmetric trench T configured such that the first area 160A and the second area 160B have different heights and the first side surface 161D and the second side surface 162D have different angles.

Also, in the light emitting display device according to the present disclosure, at the side surface of the master substrate 10, the first, third, and second areas 160A, 160C, and 160B of the bank 160 may be disposed in a first direction of the master substrate 10. At the same time, the bank 160 included in the first outer line area OLA may be disposed such that the second area 160B is closer to the central area CA than the first area 160A. The bank 160 included in the active area 13 of the second outer line area OLB may be disposed such that the second area 160B is closer to the central area CA than the first area 160A. That is, the bank 160 may be disposed symmetric with respect to the central area CA at the first outer line area OLA and the second outer line area OLB.

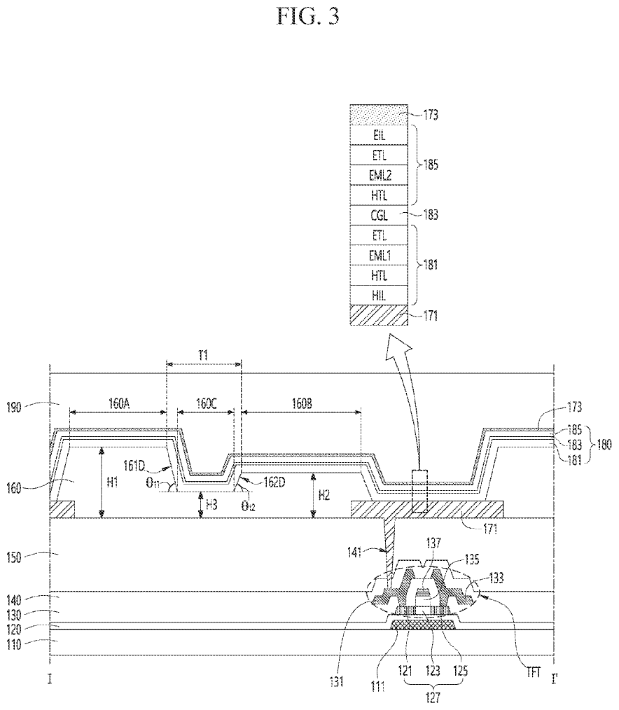

FIG. 3 is a sectional view taken along line I-I′ of FIG. 2. As shown in FIG. 3, the light emitting display device according to the present disclosure may include a substrate 110, a thin film transistor TFT, a shielding layer 111, a buffer film 120, an interlayer dielectric 130, a passivation layer 140 (or a protective layer), and an overcoat layer 150 (or a planarization layer), and may include a light emitting element including an anode 171, a light emitting unit 180, and a cathode 173, a bank 160, and an encapsulation layer 190 configured to cover the bank 160 and the light emitting element on the overcoat layer 150.

The substrate 110 is divided into an active area, in which an image is displayed, and an outer area, in which no image is displayed. The active area includes a plurality of emissive portions and a non-emissive portion other than the emissive portions. Here, the substrate 110 may be a glass substrate or a flexible plastic substrate. As an example, the plastic substrate may include polyimide or polyamide. In addition, a circuit element including various signal lines, such as data signal lines and gate signal lines, transistors, such as a switching thin film transistor and a driving thin film transistor, and a capacitor is formed for each emissive portion on the substrate 110. In the present disclosure, an arbitrary thin film transistor TFT configured to drive an emissive portion is shown for convenience of description.

Viewing FIG. 3, the thin film transistor TFT includes an active layer 127, a gate electrode 137 overlapping a channel area 123 of the active layer 127 via a gate insulation film 135, and a source electrode 131 and a drain electrode 133 connected to both sides of the active layer 127.

A source area 121 and a drain area 125 are provided at both sides of the active layer 127 of the thin film transistor TFT in the state in which the channel area 123 is located therebetween. Each of the source area 121 and the drain area 125 is formed of a semiconductor material doped with an n-type or p-type dopant. The channel area 123 overlapping the gate electrode 137 may be formed of a semiconductor material doped with no n-type or p-type dopant.

The gate electrode 137 of the thin film transistor TFT overlaps the channel area 123 of the active layer 127 so as to have the same width in the state in which the gate insulation film 135 is located therebetween. The gate insulation film 135 overlaps the channel area 123 of the active layer 127 in the same pattern as the gate electrode 137. For example, the gate electrode 137 may have a single layer structure or a multilayer structure made of any one of molybdenum (Mo), aluminum (Al), chromium (Cr), gold (Au), titanium (Ti), nickel (Ni), neodymium (Nd), and copper (Cu) or an alloy thereof. Meanwhile, the gate insulation film 135 may be made of an inorganic insulation material. For example, the gate insulation film 135 may be constituted by a silicon oxide film (SiOx), a silicon nitride film (SiNx), a silicon oxynitride film (SiOxNy), or a multilayer film thereof.

The shielding layer 111 is disposed on the substrate 110. The shielding layer 111 overlaps at least the channel area 123 of the active layer 127 of the thin film transistor TFT, and is disposed under the active layer 127. The shielding layer 111 prevents external light from penetrating the substrate 110 and reaching the thin film transistor TFT. For example, the shielding layer 111 may have a single metal layer structure made of molybdenum (Mo), titanium (Ti), aluminum-neodymium (AlNd), aluminum (Al), chromium (Cr), or an alloy thereof or a multilayer structure including the same.

The buffer film 120 is disposed on the substrate 110 including the shielding layer 111. The buffer film 120 is configured to cover the shielding layer 111. For example, the buffer film 120 may have a single layer structure or a multilayer structure made of silicon oxide (SiOx) or silicon nitride (SiNx).

The interlayer dielectric layer 130 is disposed on the buffer film 120 including the active layer 127, the gate electrode 137 and the gate insulation film 135 of the thin film transistor TFT. The interlayer dielectric layer 130 may include a source contact hole and a drain contact hole, through which the source area 121 and the drain area 125 of the active layer 127 are exposed, respectively, and may be configured to cover the gate insulation film 135 and the gate electrode 137. For example, the interlayer dielectric layer 130 may be made of an inorganic insulation material. For example, the interlayer dielectric layer 130 may be constituted by a silicon oxide film (SiOx), a silicon nitride film (SiNx), a silicon oxynitride film (SiOxNy), or a multilayer film thereof.

The source electrode 131 and the drain electrode 133 may be provided on the interlayer dielectric layer 130 as the same layer. The source electrode 131 and the drain electrode 133 are connected to the source area 121 and the drain area 125 of the active layer 127 through the source contact hole and the drain contact hole, respectively. For example, when each of the source electrode 131 and the drain electrode 133 is a single layer, each of the source electrode 131 and the drain electrode 133 may be made of any one selected from the group consisting of molybdenum (Mo), aluminum (Al), chromium (Cr), gold (Au), titanium (Ti), nickel (Ni), neodymium (Nd), and copper (Cu) or an alloy thereof.

The passivation layer 140 is disposed on the interlayer dielectric layer 130 including the source electrode 131 and the drain electrode 133. The passivation layer 140 may be configured to cover the thin film transistor TFT. As a result, the thin film transistor TFT may be protected by the passivation layer 140. For example, the passivation layer 140, which is a kind of inorganic dielectric, may be constituted by a single layer made of a silicon oxide film (SiOx), a silicon nitride film (SiNx), or a silicon oxynitride film (SiOxNy) or a multilayer film thereof.

The overcoat layer 150 may be provided on the passivation layer 140. The passivation layer 140 and the overcoat layer 150 include an anode contact hole 141, through which the drain electrode 133 of the thin film transistor TFT are exposed. Depending on circumstances, the passivation layer 140 may be omitted when the overcoat layer 150 has a function of protecting the thin film transistor TFT. For example, the overcoat layer 150, which is a kind of organic dielectric, may be made of any one of photo acrylic, polyimide, benzocyclobutene resin, and acrylate. Depending on circumstances, the overcoat layer 150 may be formed so as to have a multilayer structure.

The anode 171, which is connected to the drain electrode 133 via the anode contact hole 141, is provided on the overcoat layer 150. The anode 171 may include an emissive portion, which emits light, divided by the bank 160. Here, the emissive portion of the anode 171 may be an area that emits any one of red light, green light, blue light, and white light.

A light emitting unit 180, in which a lower stack 181, a charge generation layer 183, and an upper stack 185 are sequentially layered, is provided on the anode 171 and the bank 160, and a cathode 173 is provided opposite the anode 171 in the state in which the light emitting unit 180 is located therebetween.

Specifically, the lower stack 181 of the light emitting unit 180 may include a hole injection layer HIL, a hole transport layer HTL, a lower emissive layer EML1, and an electron transport layer ETL, and the upper stack 185 of the light emitting unit 180 may include a hole transport layer HTL, an upper emissive layer EML2, an electron transport layer ETL, and an electron injection layer EIL. The charge generation layer 183 may be provided between the lower stack 181 and the upper stack 185. The lower emissive layer EML1 of the lower stack 181 and the upper emissive layer EML2 of the upper stack 185 may be the same color emissive layers. Although, in the present disclosure, the light emitting unit 180 is a two-stack light emitting unit including the lower stack 181 and the upper stack 185, the present disclosure is not limited thereto, and the light emitting unit 180 may include two or more stacks.

A material included in the light emitting unit 180 provided between the anode 171 and the cathode 173 is not limited to an organic material. Depending on optical characteristics and electrical characteristics, at least one layer of the light emitting unit 180 may include an inorganic material or a co-deposited material including an organic material and an inorganic material. Depending on circumstances, an inorganic material may be included in an organic material as 30 wt % or less of a dopant, and an organic material may be included in an inorganic material as 30 wt % or less of a dopant.

The charge generation layer 183 provided between the lower stack 181 and the upper stack 185 may include an n-type charge generation layer and a p-type charge generation layer. The n-type charge generation layer and the p-type charge generation layer may include an n-type dopant and a p-type dopant, respectively. For example, the n-type dopant may include a metal dopant, such as lithium (Li) or ytterbium (Yb). The metal dopant may increase charge mobility. When the n-type charge generation layer is commonly formed at a plurality of subpixels, therefore, leakage current may flow between adjacent subpixels. In addition to the n-type charge generation layer, layers of the light emitting unit 180 including a material that exhibits high charge mobility may cause leakage current.

In the light emitting display device according to the present disclosure, a first trench structure T1 may be provided in the bank 160 between adjacent subpixels to cause the length of a lateral movement path between the adjacent subpixels to be increased, and therefore it is possible to greater reduce or prevent leakage current.

As shown in FIG. 3, a plurality of first trench structures T1 may be included in the bank 160 between the adjacent subpixels. The bank 160 has three portions, a first portion 160A having a height H1, a second portion 160B having a height H2 and a third portion 160C, which is the trench having a height H3. Having the portion 160B that is the reduced height H2 aids in ensuring that the trench T1 is more evenly filled with the layers 181, 183, 185 and 173.

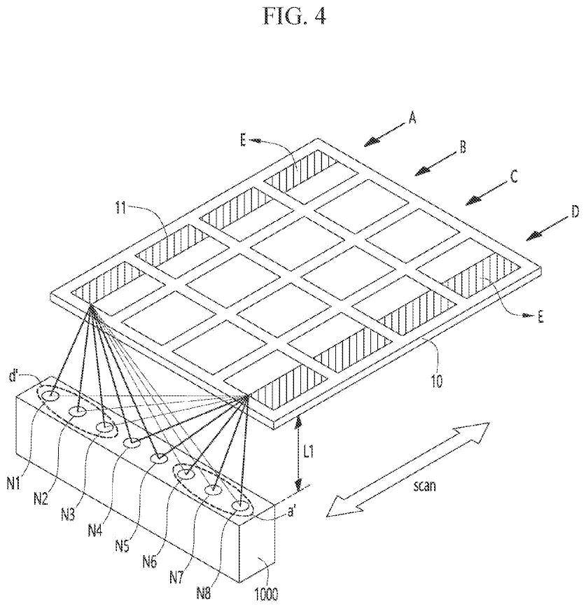

In addition, the first and second side surfaces 161D and 162D of the first trench structure T1 may be more highly tapered, namely having a greater slope, than the side surface of the bank 160. When an organic material is deposited, therefore, the amount of the material that is deposited may be less under the same conditions. This will be described in detail with reference to FIGS. 4 to 6.

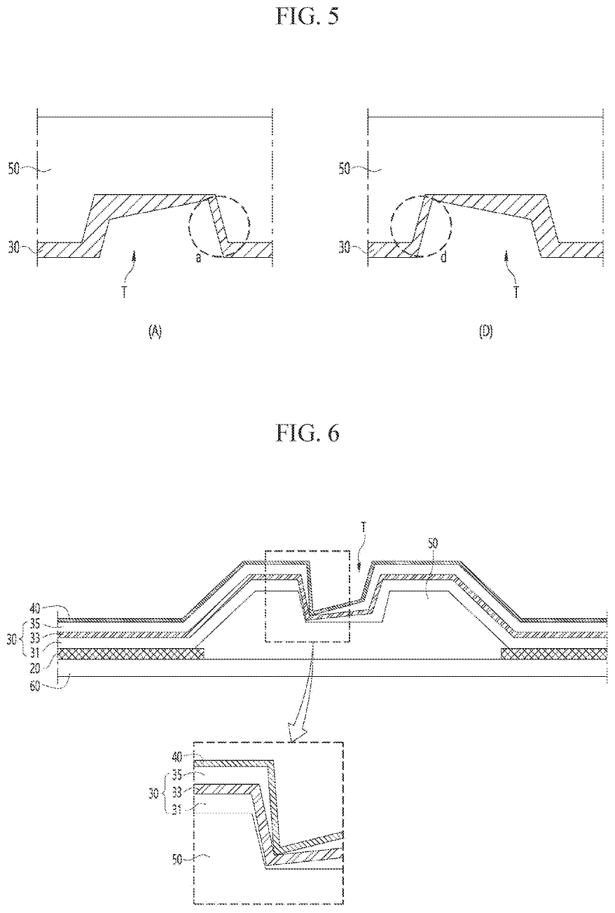

FIG. 4 is a sectional view showing some of a process of manufacturing the light emitting display device according to the present disclosure, FIG. 5 is a partial sectional view the comparative art of column A and column D when the process of FIG. 4 is carried out, and FIG. 6 is a partial sectional view of a general light emitting display device of the comparative art in which short circuit may occur in the process of FIG. 4.

Referring to FIG. 4, which is an isometric view showing some of a process of manufacturing the light emitting display device according to the present disclosure. The substrate as shown in FIGS. 1-3 is inverted, with the bank 160 facing a deposition source 1000. The method of making the light emitting display device according to the present disclosure may include a deposition source 1000 below the master substrate 10. The deposition source 1000 includes a plurality of nozzles N (N1, N2, N3, N4, N5, N6, N7, and N8) arranged in a direction parallel to the first direction, and a source is sprayed from the plurality of nozzles N. The deposition source 1000 deposits the material on the master substrate 10 while scanning the master substrate 10 at a first vertical distance L1 from the master substrate 10 in a second direction perpendicular to the first direction of the master substrate 10.

To illustrate the issues of the comparative art, an area E of column A and column D of FIG. 4 will be explained. In the location of area E, as marked on FIG. 4 with diagonal shading lines, some of the material to form the OLED is not sufficiently deposited on some regions the outer part of the master substrate 10. The reason for this is that the amount of the source material sprayed to the outer part at area E of the master substrate 10 in a direction perpendicular thereto is not as uniform and can be less in thickness than the amount of the source material sprayed to the central area in a direction perpendicular thereto. Most of the source material sprayed to the outer part area E of the master substrate 10 is partially in a lateral direction rather than directly perpendicular. As a result, the source material sprayed in the lateral direction generates a shadow with a structure on the master substrate 10, whereby the same amount of the source material that makes up the OLED is not deposited in the trench structure T1.

Viewing FIG. 5, which shows area E of column A from FIG. 4, the source material sprayed from the first to fifth nozzles N1, N2, N3, N4, and N5 may reach the shadow area of the structure. However, the source sprayed from the sixth to eighth nozzles N6, N7, and N8, which is incident at a smaller acute angle than the source sprayed from the first nozzle N1 so as to be incident perpendicularly onto column A, is not deposited on the shadow area of the structure. As a result, the area as shown in FIG. 5 at the region (A) FIG. 4, the source material for the OLED may be thinly deposited in area a, compared to the other areas on the bank. Similarly, in area E of column D from FIG. 4, the source sprayed from the first to third nozzles N1, N2, and N3, which is incident at a smaller acute angle than the source sprayed from the eighth nozzle N8 so as to be incident perpendicularly onto column D, is not deposited on the shadow area of the structure. As a result, the area as shown in FIG. 5 at the region (D) from FIG. 4, the source may be thinly deposited in area d, compared to the other areas on the bank. Here, the structure may be a bank 50 of the comparative art, and the shadow area may be the side surface of the trench T of the bank 50 in a direction in which the source to be deposited is incident. Keeping in mind that FIG. 5 shows the trench T inverted from that of FIG. 3 because during the deposition of the material from the deposition source 1000, the master substrate 10 is facing downward and the nozzles spray upward and the bank of the comparative art 50 is in a corresponding location to the bank 160 of the present disclosure. In addition, the deposited source material may be a light emitting unit 30 of the light emitting display device.

Particularly, referring to FIG. 2, among the trenches T between the plurality of emissive portions, the trench T provided between the first emissive portion EA1 and the second emissive portion EA2 is configured such that the side surface of the trench having the same direction as the incidence direction of the source is wide. Consequently, the area of the side surface of the trench T provided between the first emissive portion EA1 and the second emissive portion EA2 on which the source is not deposited may be greater than the area of the side surface of each of the trenches provided between the other emissive portions (the trenches provided between the first emissive portion EA1, the second emissive portion EA2, and the third emissive portion EA3 of FIG. 2).

The problem created by the comparative art is explained in more detail as shown in FIG. 6, the source material of the light emitting unit 30 may be thinly deposited at the trench T of the bank 50. (The structure as shown in FIG. 6 is in the same orientation as FIG. 3, which inverted from FIG. 5.) Specifically, as shown in FIG. 6, a general light emitting display device may include a plurality of anodes 20 provided on a substrate 60 and a bank 50 configured to divide emissive portions of the plurality of anodes 20 from each other, the bank including a trench T, wherein a light emitting unit 30 including a lower stack 31, a charge generation layer 33, and an upper stack 35 and a cathode 40 may be sequentially provided on the plurality of anodes 20 and the bank 50.

In the master substrate 10, the organic material may not be locally deposited between the side surface and the bottom surface of the trench T on the outer line distant from the source. That is, the light emitting unit 30 may be sufficiently deposited on the side surface of the bank 160, whereas the light emitting unit 30 may be very thinly deposited on the side surface of the trench T steeper than the side surface of the bank 160.

As a result, the thickness of an organic material (the upper stack 35 of FIG. 6) to be provided in a vertical space between the charge generation layer 33 and the cathode 40 may also be reduced, resulting in short circuit that may occur between the charge generation layer 33 and the cathode 40. When short circuit occurs between the charge generation layer 33 and the cathode 40, electrons from the cathode 40 may be introduced into the charge generation layer 33, and the electrons may flow to an outer part of the anode 20 adjacent thereto, causing the subpixel adjacent thereto to incorrectly emit light when it should not be turned on.

In particular, since the organic material supplied from the source is supplied to the trench T of the bank 50 provided in the first and second outer line areas OLA and OLB of the master substrate 10 at a small acute angle, the source of the organic material may be sufficiently deposited on the side surface laid at an angle opposite the angle of incidence, which is a part of the area of the trench T of the bank 50, whereas the organic material may be very thinly deposited on the side surface of the trench T laid in the same direction as the angle of incidence or perpendicular thereto. When the organic material of the upper stack 35 is not deposited, short circuit may occur between the charge generation layer 33 and the cathode 40 depending on circumstances.

In particular, as shown in FIGS. 1 and 5, the organic material from the source is commonly incident on the active area 13 in the first and second outer line areas OLA and OLB of the master substrate 10 at a small acute angle in a vertical line direction of FIG. 1.

As a result, as shown in FIG. 5, short circuit may continuously occur between the cathode 40 on the light emitting unit 30 and the charge generation layer 33 in the light emitting unit 30 due to the organic material deposited in the first and second outer line areas OLA and OLB of the master substrate 10, which may be observed through a phenomenon in which linear non-emission occurs.

Meanwhile, a large amount of the source material of the organic material of the light emitting unit 30 is sprayed in a relatively vertical direction at the trench T of the bank 50 provided in the central area CA of the master substrate 10, whereby the organic material of the light emitting unit 30 may be uniformly deposited.

In the light emitting display device according to the present disclosure, therefore, the first trench structure T1 of the bank 160 is provided, wherein the first trench structure T1 is configured to have a structure in which the first height H1 of the first area 160A and the second height H2 of the second area 160B of the bank 160 are different from each other and the second side angle θt2 of the second side surface 162D between the second area 160B and the third area 160C is less than the first side angle θt1 of the first side surface 161D between the first area 160A and the third area 160C such that the source of the organic material is sufficiently deposited irrespective of the angle of incidence, whereby short circuit between the cathode 173 and a layer having high charge mobility (the charge generation layer 183 of FIG. 2) is prevented. First and second embodiments of the light emitting display device according to the present disclosure may be different from each other in terms of the side angle of the bank 160 and the height difference for each area. The term “area” is used herein in to refer to sidewall structure and area, such as a top or side of a what is 3 dimensional structure having a volume. As will be appreciated, some of the references herein to area refer to an area on the surface or a side of a structure and thus refer to the size of an area, such as square microns, square Angstroms, square nanometers and the like. For other structures herein, the term area is used with respect to a cross-sectional view or a side view of that structure, but the structure itself occupies a volume on the substrate. For example, bank 50 and other banks herein occupy a volume and thus can also be expressed in terms of microns cubed, Angstroms cubed and the like if the full volume of the structure is being characterized. Thus, references here to the area of a bank is just for two of the dimensions and the bank will also have a depth dimension to fill a volume. While the measurement of the area is with reference to the sidewall in a cross section having a height and width, the bank itself also has a depth extending in a third dimension and thus occupies a volume. For example, FIG. 2 provides a top view, which would provide depth information that can be combined with the measurements and information in the cross sectional side views that provide an area as shown in FIG. 3 and other Figures herein so that the volume of the bank can be understood.

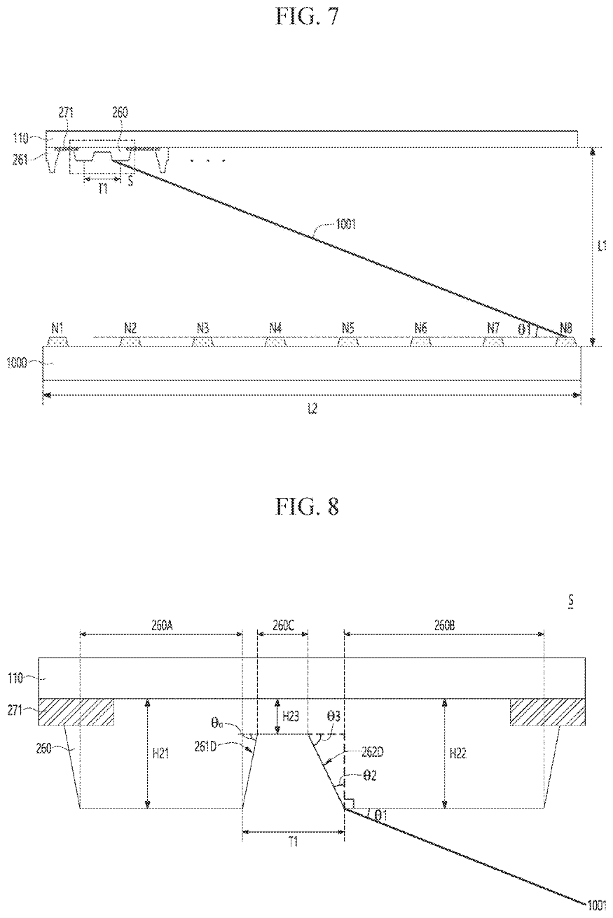

FIGS. 7 and 8 are partial side views and a partial sectional views of a light emitting display device according to a first embodiment of the present disclosure and a deposition source, wherein a taper angle θ2 of a second side surface 262D of a bank 260 is shown. The scale of FIG. 7 is small, therefor the angle differences are more easily seen in the enlarged section S of FIG. 8.

Referring to FIG. 7, the light emitting display device according to the present disclosure may include a plurality of anodes 271 provided on a master substrate 110 and a bank 260 configured to divide emissive portions of the plurality of anodes 271 from each other, the bank including a first trench structure T1. In the light emitting display device according to the embodiment of the present disclosure, the first trench structure T1 may be provided between two adjacent ones of the plurality of anodes 271, and a spacer 261 may be further provided at the outside of each of the two anodes 271 excluding the area of a bank 260 having the first trench structure T1. In addition, a thin film transistor TFT, which is connected to the anodes 271, may be provided on the master substrate 110. The thin film transistor TFT is not shown in FIGS. 7 and 8 for ease of illustration, but is present in a manner as shown in FIG. 3.

The spacer 261 may have a height greater than the height of a first area 260A, which is the highest of the bank 260, and may be tapered such that the width of the spacer 261 is gradually increased toward the master substrate 110. The spacer 261 serves to support a fine metal mask (FMM) during a process.

In the first embodiment of the present disclosure, a deposition source 1000 including first to eighth nozzles N (N1, N2, N3, N4, N5, N6, N7, and N8) arranged at uniform intervals may be provided opposite the master substrate 110. The deposition source 1000 may spray a source from the plurality of nozzles N toward the master substrate 110. As an example, the eighth nozzle N8, which is located at one end of the deposition source 1000, may spray the source along a deposition boundary line 1001 toward the first trench structure T1 of the bank 260 located at the other end of the master substrate 110. At this time, the vertical distance between the master substrate 110 and the deposition source 1000 may be a first distance L1, and the master substrate 110 and the deposition source 1000 may have the same width. A second distance L2 is the distance from the end of the deposition source 1000 at which the first nozzle N1 is located to an n-th nozzle Nn (n being a natural number).

Here, the second distance L2 is defined as the distance from the first nozzle N1 to the n-th nozzle Nn for convenience of description. Specifically, the second distance L2 is the horizontal distance from a structure to be deposited (the bank 260 of FIG. 6) to the nozzle used for deposition. For example, when the source sprayed from the first nozzle located at the end of the deposition source to the sixth nozzle (the distance from the first nozzle to the sixth nozzle is equal to the distance from the end of the deposition source to the sixth nozzle and the distance from the first nozzle to the sixth nozzle is assumed as Y) is deposited on the structure distant from the end of the substrate by a predetermined distance (assumed as X), the second distance L2 is Y-X. For convenience of description, therefore, the second distance L2 according to the first embodiment is defined as the length of the deposition source 1000, which is the horizontal distance from the bank 260 located at one end of the substrate 110 to the eighth nozzle N8 located at the other end of the deposition source 1000.

The second angle θ2 of the second side surface 262D of the bank 260 according to the first embodiment of the present disclosure will be described with reference to FIG. 8, which is an enlarged view of area S of FIG. 7. Referring to FIG. 8, a first area 260A and a second area 260B of the bank 160 may respectively have a first height H21 and a second height H22, which are equal to each other, and a third area 260C between the first area 260A and the second area 260B may have a third height H23, which is less than the height of each of the first area 260A and the second area 260B.

In addition, a third angle θ3 of the second side surface 262D of the bank 260 according to the first embodiment may be different from a first side angle θa of a first side surface 261D. That is, the bank 260 according to the first embodiment may be configured such that the second angle θ2 of the second side surface 262D, which is the taper angle, is greater than the taper angle of the first side surface 261D. As described above, the second side surface 262D may be gentler, namely have lower slope than the slope of first side surface 261D. Specifically, the interior angle between the second side surface 262D and the deposition boundary line 1001 may be 129° or more.

When the interior angle between the second side surface 262D and the deposition boundary line 1001 is 129° or more, the source sprayed to the second side surface 262D along the deposition boundary line 1001 may be deposited on the second side surface 262D over the bank 260. Consequently, the relationship between the second side surface 262D and the deposition boundary line 1001 may be represented by Expression 1 below.

$$θ 1 + θ2 + 90 ° \geq 129 ° \qquad Expression 1$$

In Expression 1, θ1 is a first angle θ1, which is the angle of incidence of the deposition boundary line 1001, and θ2, which is the taper angle of the second side surface 262D, is a second angle θ2, which is the interior angle between the second side surface 262D and a plane perpendicular to the substrate 110. In addition, θ2+90° is the angle between the second side surface 262D and the surface of the second area 260B of the bank 260. Meanwhile, θ3 is a third angle θ3, which is the interior angle between the second side surface 262D and the substrate 110. Meanwhile, the second angle θ2 and the third angle θ3 have a relationship of θ2=90°−θ3.

Referring to FIG. 7, on the assumption that the vertical distance between the substrate 110 and the deposition source 1000 is a first distance L1 and the width of the deposition source 1000 is a second distance L2, the first angle θ1 may converge on arctan(L1/L2). The bank 260 shown in FIG. 7 occupies a large part of the substrate 110. In order to divide emissive portions of a plurality of subpixels provided on the substrate 110 from each other, however, the bank 260 is locally provided between the emissive portions, and therefore the actual size of the bank 260 between the emissive portions is considerably less than the size of the master substrate 110. Consequently, the first angle θ1 may converge on arctan(L1/L2). When this is applied, therefore, a relationship of the second angle θ2 may be represented by Expression 2 below.

$$θ 2 \geq 39 ° - arc tan ( L 1 / L 2 ) \qquad Expression 2$$

In the present disclosure, as represented by Expression 2, the second angle θ2 may be equal to or greater than 39°−arctan(L1/L2) such that all of the source from the first to eighth nozzles N1 to N8 is deposited on the second side surface 262D of the first trench structure T1 of the bank 260 located at the end of the substrate 110. In order to perform the function of the first trench structure T1 of the bank 260, however, the third angle θ3 has a value less than 90°.

As an example, when the first distance L1 between the substrate 110 and the deposition source 1000 is 340 mm and the second distance L2 of the deposition source 1000 is 925 mm, the first angle θ1 may be 20°. In this case, the second angle θ2 may range from a minimum of 19° (39°−20°=19°) to a maximum of less than 90°, and therefore the source sprayed from the first to eighth nozzles N1 to N8 may be deposited on the second side surface 262D.

Consequently, the bank 260 according to the first embodiment of the present disclosure may have a first trench structure T1 in which the first area 260A and the second area 260B have the same height and the first side surface 261D, the third area 260C, and the second side surface 262D are asymmetric. In addition, the second angle θ2, which is the taper angle of the second side surface 262D of the bank 260 according to the first embodiment, may be 39°−arctan(L1/L2). In the first embodiment of the present disclosure, therefore, the height of the upper surface of the bank 260 may be uniform, and the taper angle of the second side surface 262D having the same direction as the deposition boundary line 1001 of the source may be changed, whereby the source sprayed from the first to eighth nozzles N1 to N8 may be deposited on the bottom surface of the first trench structure T1 (the upper surface of the third area 260C) and the second side surface 262D.

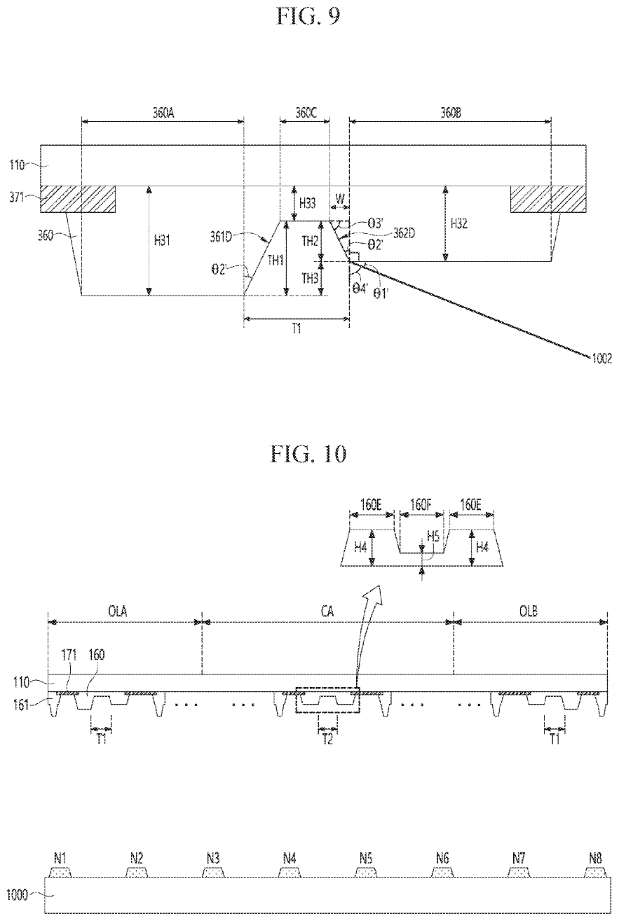

Turning now to FIG. 9, a second height H32 of a second area 360B of a bank 360 will be described in detail with reference to FIG. 9, which is a sectional view of a light emitting display device according to a second embodiment of the present disclosure. A description of the construction of the second embodiment that is identical to FIG. 8 will not be omitted for simplicity. Keeping in mind that the structure of FIG. 9 is shown inverted from the view of FIG. 3 because it is being viewed from the process of manufacture as shown in FIG. 4 with the master substrate 110 facing downward.

Referring to FIG. 9, the bank 360, when viewed in cross-section, may include a first area 360A having a first height H31, a second area 360B having a second height H32 less than the first height H31, and a third area 360C provided between the first area 360A and the second area 360B, the third area 360C having a third height H33 less than the second height H32. In addition, the bank 360 may have a first side surface 361D between the first area 360A and the third area 360C and a second side surface 362D between the second area 360B and the third area 360C, wherein the taper angle of the first side surface 361D and the taper angle of the second side surface 362D are equal to each other. The taper angle of each of the first side surface 361D and the second side surface 362D is a second angle θ2′. That is, in the second embodiment of the present disclosure, the first height H31 and the second height H32 of the first area 360A and the second area 360B of the bank 360 may be different from each other.

Referring to FIG. 9, TH1 is a first height difference TH1, which is the height difference between the first area 360A and the third area 360C, and TH2 is a second height difference TH2, which is the height difference between the second area 360B and the third area 360C. 04′ is a fourth angle θ4′, which is the interior angle between a deposition boundary line 1002 and a plane perpendicular to the substrate 110, and 02′, which is the taper angle of the second side surface 362D, is a second angle θ2′, which is the interior angle between the second side surface 362D and the plane perpendicular to the substrate 110. Meanwhile, θ1′ is a first angle θ1′, which is the angle of incidence of the deposition boundary line 1002, and θ3′ is a third angle θ3′, which is the interior angle between the second side surface 362D and the substrate 110. W is a first width W by which the taper of the second side surface 362D occupies the substrate 110 in section.

In addition, the second height H32 of the second area 360B according to the second embodiment of the present disclosure may be uniform in the second area 360B, as shown in FIG. 8, or may be gradually increased with increase in distance from the third area 360C, unlike FIG. 8.

Here, that the second height H32 is gradually increased with increase in distance from the third area 360C means that the second height H32 is not uniform in the second area 360B. When the second height H32 is not uniform, the height of the second area 360B must be less than the height of the deposition boundary line 1002 such that the deposition boundary line 1002 of the source incident on the third area 360C is not hidden.

Next, an example of the second height difference TH2 will be described. As an example, when, in the bank 360 on the substrate 110 opposite the first nozzle N1, the first distance L1, which is the vertical distance between the substrate 110 and the deposition source 1000, is 340 mm and the second angle θ2′ is 20°, the second height difference TH2 of the second area 360B may be given as shown in Table 1 below. Meanwhile, the second distance L2 is the distance from the end of the deposition source 1000 at which the first nozzle N1 is located to the n-th nozzle Nn.

TABLE 1

| | Nozzle | | | Second |
|---|---|---|---|---|
| | number (Nn) | Second | | height |
| | (n being a | distance | Fourth angle | difference |
| Experimental | natural | (L2) | (θ4′) | (TH2) |
| example | number) | (unit: mm) | (θ4′ = 90° − θ1′) | (unit: μm) |
| 1 | 1N | 0 | 0.0 | 1 |
| 2 | 2N | 264.3 | 37.9 | 0.47 |
| 3 | 3N | 528.6 | 57.2 | 0.23 |
| 4 | 4N | 792.9 | 66.8 | 0.16 |
| 5 | 5N | 1057.1 | 72.2 | 0.12 |
| 6 | 6N | 1321.4 | 75.6 | 0.09 |
| 7 | 7N | 1585.7 | 77.9 | 0.08 |
| 8 | 8N | 1850.0 | 79.6 | 0.07 |

Table 1 above is an experiment table showing the second height difference TH2 by which the source sprayed from the n-th nozzle Nn can be deposited on the second side surface 362D when L1 is 340 mm and θ2′ is 20°. In this case, the bank 360 is located at the end of the substrate 110, and is opposite the first nozzle N1.

Experimental example 1 is the second height difference TH2 formed such that the source sprayed from the first nozzle N1 can cover the second side surface 362D of the bank 360. That is, Experimental example 1 shows that the second height difference TH2 is 1 μm when the source sprayed from the first nozzle N1 at an angle of inclination of 0° is deposited on the second side surface 362D provided at the position opposite the first nozzle N1.

Experimental example 2 is the second height difference TH2 formed such that the source sprayed from the second nozzle N2 can cover the second side surface 362D of the bank 360. That is, Experimental example 2 shows that the second height difference TH2 necessary for the source sprayed from the second nozzle N2 at an angle of inclination of 37.9° to be deposited on the second side surface 362D provided at the position opposite the first nozzle N1 is 0.47 μm. In this case, the source sprayed from the first nozzle N1 and the second nozzle N2 may be deposited on the second side surface 362D of the bank 360.

Experimental example 3 is the second height difference TH2 formed such that the source sprayed from the third nozzle N3 can cover the second side surface 362D of the bank 360. That is, Experimental example 3 shows that the second height difference TH2 necessary for the source sprayed from the third nozzle N3 at an angle of inclination of 57.2° to be deposited on the second side surface 362D provided at the position opposite the first nozzle N1 is 0.23 μm. In this case, the source sprayed from the first to third nozzles N1 to N3 may be deposited on the second side surface 362D of the bank 360.

Experimental example 4 to Experimental example 8 show the same results as Experimental example 1 to Experimental example 3. It can be seen that, in order for the source sprayed from the eighth nozzle N8 farthest from the bank 360 to be deposited on the second side surface 362D of the bank 360, the second height difference TH2 is 0.07 μm. That is, it can be seen from Table 1 above that the second height difference TH2 of the bank is gradually reduced from the first nozzle to the eighth nozzle. In the second embodiment of the present disclosure, therefore, the second height difference TH2 may be gradually reduced with increase in distance from the nozzle opposite the bank 360 having the second side surface 362D.

The second side angle θt2 of the second side surface 162D of the bank 160 according to the first embodiment and the second height H2 formed with the second height difference TH2 according to the second embodiment may be simultaneously applied to one second side surface 162D, or only one of the first embodiment and the second embodiment may be applied. In the light emitting display device according to the present disclosure, therefore, it is possible to effectively uniformly deposit the source incident at an acute angle on the first trench structure T1 of the bank 360 through selective application of the first embodiment and the second embodiment. As an example, when a general manufacturing situation, in which a substrate having a size of 1 m or more is applied, is considered and the left and right angles of the first trench structure T1, each of which is the second angle θ2′, are equal to each other, as in the second embodiment, the second height difference TH2 may be 23% or less of the first height difference TH1. In addition, when a general manufacturing situation in which a substrate having a size of 1 m or more is applied is considered, the third angle θ3 or θ3′ of the first trench structure T1 may be 71° or less.

FIG. 10 is a sectional view of a master substrate 110 used to manufacture the light emitting display device according to the present disclosure, wherein the shape of the bank for each area is schematically shown.

Referring to FIG. 10, the master substrate 110 includes a first outer line area OLA, a second outer line area OLB, and a central area CA between the first and second outer line areas OLA and OLB in the first direction similar to that shown in FIG. 1. In addition, a deposition source 1000 may be provided opposite the master substrate 110. The deposition source 1000 is shown as including first to eighth nozzles N1 to N8 arranged at uniform intervals in the first direction; however, the present disclosure is not limited thereto.

In the light emitting display device according to the present disclosure, the bank 160 may be disposed symmetric with respect to the central area CA at the first outer line area OLA and the second outer line area OLB. In addition, the bank 160 may be disposed symmetrically relative to the first outer line area OLA and the second outer line area OLB such that the second area 160B of the bank 160, which has a relatively small height, is closer to the central area CA and the bank portion 160A that is farther from the central region of deposition source 1000 is has a greater height. In the symmetric structure of the bank 160, the source sprayed from the nozzles N of the deposition source 1000 provided in the first direction may be uniformly deposited at both the first outer line area OLA and the second outer line area OLB.

Meanwhile, the source sprayed from the nozzles is incident on the bank 160 provided in the central area CA at an approximately right angle or at an acute angle of 45° or more, whereby more uniform deposition may be achieved than in the outer line areas. Consequently, the bank 160 provided in the central area CA of the light emitting display device according to the present disclosure may have a second trench structure T2 different from the first trench structure T1. The second trench structure T2 provided in the central area CA may include fourth areas 160E each having a fourth height H4 equal to the first height H1 and a fifth area 160F between the fourth areas 160E, the fifth area 160F having a fifth height H5 equal to the third height H3. That is, the bank 160 provided in the central area CA may be disposed in left-right symmetry with respect to the second trench structure T2.

Furthermore, the light emitting display device according to the present disclosure may further include a spacer 161 formed so as to have a larger height than the first area 161A of the bank 160. The spacer 161 may be tapered such that the width of the spacer 161 is gradually increased toward the substrate 110. Based on two anodes 171, the spacer 161 may be provided at an outer area of each of the two anodes 171 excluding a bank 160 having a first or second trench structure T1 or T2 between the two anodes 171.

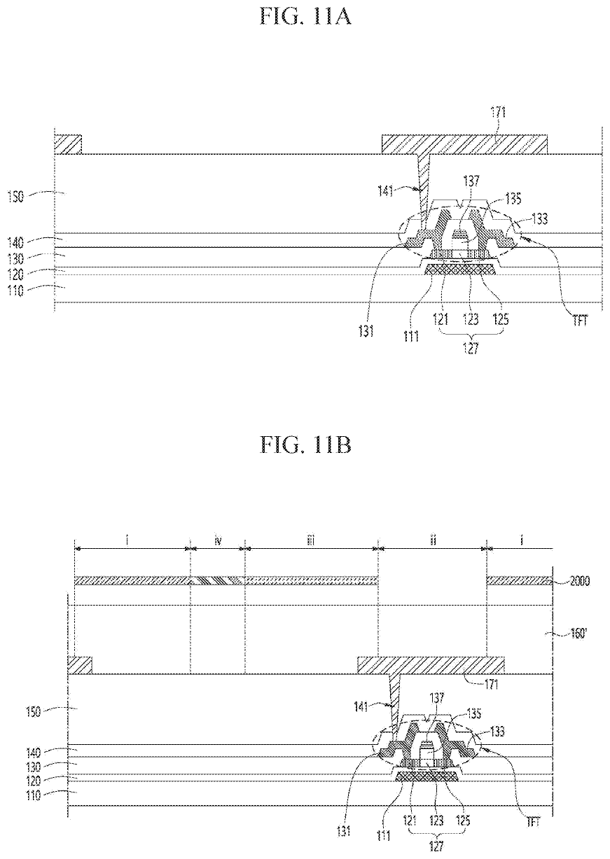

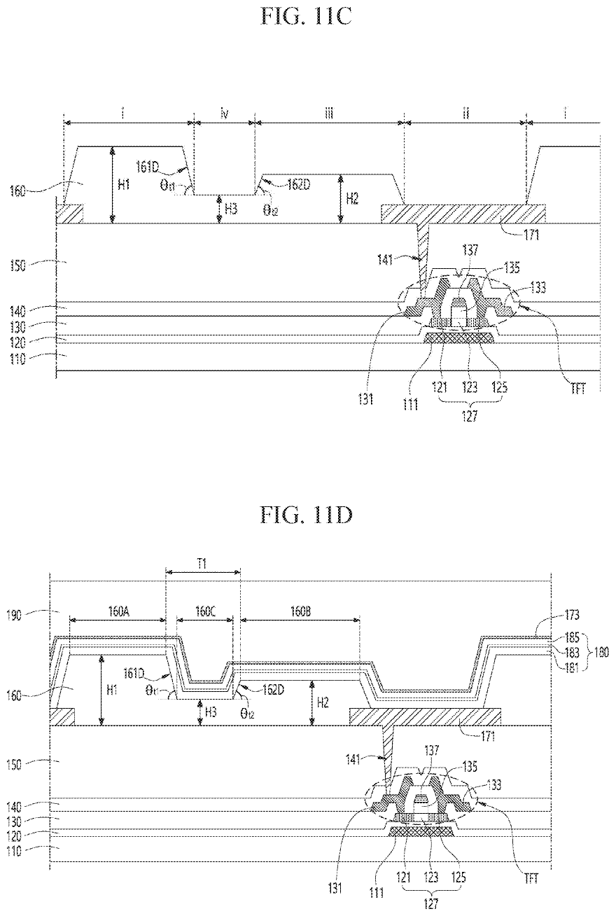

Next, a manufacturing method to build the embodiments of FIGS. 2-4 and 9-10 will be will be described with reference to FIGS. 11A to 11D.

Referring to FIG. 11A, a shielding layer 111, a buffer film 120, and a thin film transistor TFT are sequentially formed on a substrate 110. Specifically, a buffer film 120 is formed on a substrate 110 having a shielding layer 111 formed thereon, and an active layer 127 is formed on the buffer film 120 through a mask process. Subsequently, a gate insulation film 135 is formed on the buffer film 120 having the active layer 127 formed thereon, and a gate electrode 137 is formed on the gate insulation film 135. The gate insulation film 135 and the gate electrode 137 are simultaneously formed through a mask process. Subsequently, an interlayer dielectric 130 having source and drain contact holes is formed on the gate electrode 137 through a mask process. Subsequently, source and drain electrodes 131 and 133 are formed on the substrate 110 having the interlayer dielectric 130 formed thereon through a mask process. Subsequently, a passivation layer 140 having an anode contact hole 141 and an overcoat layer 150 are sequentially layered on the interlayer dielectric 130 having the source and drain electrodes 131 and 133 formed thereon. Subsequently, an anode 171 electrically connected to the drain electrode 133 of the thin film transistor TFT through the anode contact hole 141 is formed on the overcoat layer 150.

Next, referring to FIG. 1113, a bank material 160′ is entirely formed on the overcoat layer 150 having the anode 171 formed thereon. Subsequently, the bank material 160′ is exposed to light using a multi-tone mask 2000. The multi-tone mask 2000 may include (i) a blocking area that blocks light, (ii) a transmission area that transmits the entirety of light, (iii) a first semi-transmission area that transmits a part of light, and (iv) a second semi-transmission area. (iii) The first semi-transmission area and (iv) the second semi-transmission area of the multi-tone mask 2000 may be constituted by half-tone masks having different transmittances. Consequently, the bank material 160′ may be formed at different heights and different taper angles in (iii) the first semi-transmission area and (iv) the second semi-transmission area.

Next, referring to FIG. 11C, the bank material 160′ exposed to light is etched such that a first area 160A having a first height H1 is formed in (i) the blocking area, the anode 171 is exposed in (ii) the transmission area, a second area 160B having a second height H2 is formed in (iii) the first semi-transmission area, and a third area 160C having a third height H3 is formed in (iv) the second semi-transmission area. Since (iii) the first semi-transmission area and (iv) the second semi-transmission area are formed using half-tone masks having different transmittances, the second height H2 and the third height H3 are different from each other.

In addition, (i) the blocking area, (iii) the first semi-transmission area, and (iv) the second semi-transmission area, which have different transmittances, may be formed so as to have different taper angles between the first to third areas 160A, 160B, and 160C. In the light emitting display device according to the present disclosure, therefore, a first side surface 161D between the first area 160A and the third area 160C and a second side surface 162D between the second area 160B and the third area 160C may be differently formed. That is, the second side angle θt2 of the second side surface 162D of the light emitting display device according to the present disclosure may be different from the first side angle θt1 of the first side surface 161D.

Next, referring to FIG. 11D, a light emitting unit 180 having a structure in which a lower stack 181, a charge generation layer 183, and an upper stack 185 are layered and a cathode 173 may be sequentially formed on the anode 171 and the bank 160, and an encapsulation layer 190 may be formed so as to cover the cathode 173. Here, the encapsulation layer 190 is formed on the cathode 173 so as to cover the entirety of an active area and an outer area. The encapsulation layer 190 prevents permeation of oxygen and moisture into a light emitting element, thereby improving the lifespan of the light emitting display device. As an example, the encapsulation layer 190 may be formed in a structure in which an inorganic encapsulation layer and an organic encapsulation layer are layered in one or more pairs or in a structure in which a fill material and a substrate opposite thereto are layered.

In the light emitting display device according to the present disclosure, as described above, a bank having a first trench structure asymmetric to a source of a deposition source incident at a small acute angle is formed, whereby the source of the deposition source is uniformly deposited, and therefore it is possible to prevent short circuit between a cathode and a common layer having high mobility at a corner of the trench. Conventionally, a part of the trench in an area in which deposition is not uniformly performed is removed in order to prevent short circuit between the cathode and the common layer having high mobility due to nonuniform deposition. In particular, the source of the deposition source is incident on a bank provided at the edge of an active area at a small acute angle, whereby short circuit may easily occur between the cathode and the common layer having high mobility due to nonuniform deposition. In the light emitting display device according to the present disclosure, however, the first trench of the bank is asymmetrically formed, whereby the source of the deposition source is uniformly deposited on the corner of the trench, and therefore it is possible to prevent short circuit between the cathode and the common layer having high mobility in any area of the substrate. In the light emitting display device according to the present disclosure, therefore, it is possible to prevent the flow of leakage current between sides of adjacent subpixels and to prevent light leakage at the edge of the active area while not removing the trench of the bank.

Consequently, the light emitting display device according to the present disclosure may have the following effects. First, it is possible to prevent the flow of leakage current between sides of adjacent subpixels through the first trench structure. Second, since the source of the deposition source incident on the bank located at the edge of the active area at a small acute angle is not uniformly deposited in the trench of the bank, the first trench structure of the bank is asymmetrically formed in order to uniformly deposit the source of the deposition source, whereby it is possible to prevent short circuit between the cathode and the common layer having high mobility at the corner of the first trench structure. Third, it is possible to prevent short circuit between the cathode and the common layer having high mobility, whereby it is possible to prevent light leakage at the edge of the active area.

The light emitting display device according to the present disclosure may be configured as follows.

A light emitting display device according to an embodiment of the present disclosure may include a substrate having an active area, a plurality of anodes spaced apart from each other in the active area, a bank configured to expose an emissive portion of each of the plurality of anodes, the bank being provided between the emissive portions, and a light emitting unit and a cathode sequentially provided on the plurality of anodes and the bank, wherein at least a part of the bank includes a first trench structure asymmetric at both sides thereof.

In the light emitting display device according to the embodiment of the present disclosure, the first trench structure of the bank may include a first area having a first height, a second area having a second height less than the first height, and a third area provided between the first area and the second area, the third area having a third height less than the second height.

In the light emitting display device according to the embodiment of the present disclosure, the first trench structure may include a bottom surface formed as the result of the upper surface of the bank being removed by a predetermined thickness and a first side surface and a second side surface having different angles with respect to the bottom surface, the upper surface of the bank may be the first height, and the bottom surface may be the third height.

In the light emitting display device according to the embodiment of the present disclosure, the first trench structure may be provided along the edge of the active area of the substrate in one direction.

In the light emitting display device according to the embodiment of the present disclosure, the bank may further include a second symmetric trench structure.

In the light emitting display device according to the embodiment of the present disclosure, the second trench structure may include fourth areas each having a fourth height equal to the first height and a fifth area provided between the fourth areas, the fifth area having a fifth height equal to the third height.

In the light emitting display device according to the embodiment of the present disclosure, the light emitting unit may include a first stack and a second stack overlapping each other and a charge generation layer provided between the first stack and the second stack, and at least one of the second stack may be continuously provided in the first trench structure.

As is apparent from the above description, the light emitting display device according to the present disclosure has the following effects.

First, the light emitting display device according to the present disclosure has an effect in that it is possible to prevent the flow of leakage current between sides of adjacent subpixels through the first trench structure.

Second, the light emitting display device according to the present disclosure has an effect in that, since the source of the deposition source incident on the bank located at the edge of the active area at a small acute angle is not uniformly deposited in the trench of the bank, the first trench structure of the bank is asymmetrically formed in order to uniformly deposit the source of the deposition source, whereby it is possible to prevent short circuit between the cathode and the common layer having high mobility at the corner of the first trench structure.

Third, the light emitting display device according to the present disclosure has an effect in that it is possible to prevent short circuit between the cathode and the common layer having high mobility, whereby it is possible to prevent light leakage at the edge of the active area.

The present disclosure is not limited to the above embodiments and the accompanying drawings, and those skilled in the art to which the present disclosure pertains will understand that various substitutions, modifications, and alterations are possible without deviating from the technical details of the present disclosure. Therefore, the scope of the present disclosure should be interpreted that all alterations or modifications derived from the meaning and scope of the claims and equivalent concepts thereto are included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments inlightof the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a substrate having an active area;
a plurality of anodes spaced apart from each other in the active area;
a bank positioned between emissive portions of the plurality of anodes and having an opening that exposes an emissive portion of each of the plurality of anodes; and
a light emitting unit and a cathode sequentially provided on the plurality of anodes and the bank,
a first trench in the bank that is positioned between the emission portions, the first trench having two sides that are asymmetric relative to each other.

2. The light emitting display device according to claim 1, wherein the first trench structure of the bank comprises a first area having a first height, a second area having a second height less than the first height, and a third area provided between the first area and the second area, the third area having a third height less than the second height.

3. The light emitting display device according to claim 2, wherein the active area of the substrate includes a first side and a second side spaced from the first side on the substrate and the second bank area is located closer to the first side of the substrate than the first bank area is to the first side of the substrate.

4. The light emitting display device according to claim 2, further including:
a plurality of banks, each bank of the plurality being in a line extending from the first side of the substrate to the second side of the substrate, wherein the height of the second bank area is lower for those banks spaced further from the first side.

5. The light emitting display device according to claim 4, wherein the height of the second bank area gradually decreases with each bank further from the first side with the increase in distance from the third area.

6. The light emitting display device according to claim 2, wherein the first trench structure further comprises a first side surface between the first area and the third area and a second side surface between the second area and the third area.

7. The light emitting display device according to claim 3, wherein the first side surface and the second side surface have different angles with respect to the third area.

8. The light emitting device of claim 7 wherein an angle of the first side surface with respect to the top surface of the bank in the third area is smaller than an angle of the second side surface with respect to the top surface of the bank in the third area.

9. The light emitting display device according to claim 1, wherein
the first trench structure comprises a bottom surface formed as a result of an upper surface of the bank being removed by a predetermined thickness and a first side surface and a second side surface having different angles with respect to the bottom surface,
the upper surface of the bank is the first height, and
the bottom surface is the third height.

10. The light emitting display device according to claim 1, wherein the first trench structure is provided along an edge of the active area of the substrate in one direction.

11. The light emitting display device according to claim 4 wherein the plurality of banks further comprises a second bank having a second trench structure in which both sides are symmetric.

12. The light emitting display device according to claim 7, wherein the second trench structure comprises fourth areas each having a fourth height equal to the first height and a fifth area provided between the fourth areas, the fifth area having a fifth height equal to the third height.

13. The light emitting display device according to claim 1, wherein
the light emitting unit comprises a first stack and a second stack overlapping each other and a charge generation layer provided between the first stack and the second stack, and
at least one layer of the second stack is continuously provided in the first trench structure.

14. A method of manufacturing a light emitting display device, the method comprising:
moving a master substrate relative to a source material deposition nozzle;
depositing materials from the source nozzle onto the master substrate to form a plurality of pixels spaced apart from each other, each of the pixels having an active area, the master substrate including a first outer line area and a second outer line area opposite each other in a first direction, and a central area provided between the first and second outer line areas;
forming a plurality of anodes in the active area of each of the pixels;
forming a plurality of banks configured to expose an emissive portion of each of the plurality of anodes, each bank being provided between emissive portions of the plurality of anodes; and
sequentially forming a light emitting unit and a cathode on the plurality of anodes and the respective bank, wherein
a first set of banks of the plurality of banks having a first trench structure asymmetric at both sides thereof in at least one of the first outer line area and the second outer line area.

15. The method of claim 14 further including:
cutting the master substrate into a plurality of smaller substrates, each of the smaller substrates having a plurality of banks thereon.

16. The method according to claim 15, wherein the first trench structure of each bank in the first set of banks comprises a first area having a first height, a second area having a second height less than the first height, and a third area provided between the first area and the second area, the third area having a third height less than the second height.

17. The method according to claim 16, wherein the forming the first set of banks is performed using a multi-tone mask having an opening corresponding to the emissive portion of each of the plurality of anodes, the multi-tone mask having different transmittances for the first area, the second area, and the third area.

18. The method according to claim 14, wherein
the first trench structure comprises a bottom surface formed as a result of an upper surface of the bank being removed by a predetermined thickness and a first side surface and a second side surface having different angles with respect to the bottom surface,
the upper surface of the bank is the first height, and
the bottom surface is the third height.

19. A light emitting display device comprising:
a substrate having an active area;
a plurality of subpixels positioned in the active area, each subpixel having an anode on the substrate, a light emitting stack on the anode and a cathode on the light emitting stack;
a bank positioned between first sub-pixel and a second subpixel of the plurality of subpixels; and
a trench in the bank, the trench being located between the first and second subpixels,
wherein the bank has a first wall of a first height adjacent to a first side of the trench and a second wall of second, different height adjacent to second wall of the trench, the first and second walls being positioned between the first and second subpixels.

20. The light emitting display devise of claim 19 wherein the trench has a first sidewall adjacent to the first wall and a second sidewall adjacent to the second wall.

21. The light emitting device of claim 20 wherein the angle of the first sidewall relative to the first substrate is greater than the angle of the second sidewall to the relative to the substrate.

22. The light emitting device of claim 19 wherein a width of the trench is less than a width of each of the first and second walls.

23. The light emitting device of claim 19 wherein a width of the first wall is less than a width of the second wall.

24. The light emitting device of claim 19 wherein the trench is offset from a center point between the first and second subpixels.
